(19) United States
(12) Patent Application Publication
(10) Pub. No.: US 2013/0010996 A1
(43) Pub. Date: Jan. 10, 2013

(54) WELDING TYPE CONDENSER MICROPHONE USING CURLING AND METHOD OF ASSEMBLYING THE SAME

(75) Inventors: Hyoung Joo KIM, Incheon (KR); Chang Won KIM, Incheon (KR); Myung Hoon HAM, Incheon (KR)

(73) Assignee: BSE CO., LTD., Incheon (KR)

(21) Appl. No.: 13/528,108

(22) Filed: Jun. 20, 2012

(30) Foreign Application Priority Data
Jul. 9, 2011 (KR) 10-2011-0068163
Jul. 12, 2011 (KR) 10-2011-0068823

(51) Int. Cl. H04R 11/04; H05K 3/30

(52) U.S. Cl. 381/355; 29/832

(57) ABSTRACT

A condenser microphone that is manufactured by attaching components installed in a case by using curling to prevent movement of the components when the case and a printed circuit board (PCB) are welded to each other and to stably transfer electrical signals, and a method of manufacturing the condenser microphone. The condenser microphone using curling includes a case sub assembly prevented from moving by mounting a diaphragm, a spacer, a back plate, and a first base in a case with an open side and then curling an end portion of the open side; a printed circuit board (PCB); and an adhesion portion for adhering the case sub assembly and the PCB sub assembly to each other. A curling portion is formed on the end portion of the open side of the metal case and is curled. In addition, slits are formed in opposite lower ends of the curling portion.

### CROSS-REFERENCE TO RELATED PATENT APPLICATION

This application claims the benefit of Korean Patent Application Nos. 10-2011-0068163, filed on Jul. 9, 2011, and 10-2011-0068823, filed on Jul. 12, 2011 in the Korean Intellectual Property Office, the disclosures of which are incorporated herein in their entirety by reference.

### BACKGROUND OF THE INVENTION

1. Field of the Invention

The present invention relates to a welding type condenser microphone, and more particularly, to a welding type condenser microphone that is manufactured by closely attaching components installed in a case by using curling so as to prevent movement of the components when the case and a printed circuit board (PCB) are welded to each other and to stably transfer electrical signals, and a method of manufacturing the welding type condenser microphone.

2. Description of the Related Art

In general, as shown in FIG. 1, a welding type condenser microphone 10 includes a metal case 11 having a front surface through which a sound hole 11a is formed, a diaphragm 12, a spacer 13, a first base 14 (which is also referred to as an insulating base) formed of an insulator and having a ring shape, a back plate 15 facing the diaphragm 12 with the spacer 13 disposed therebetween, a second base 16 (which is also referred to as a conductive base) formed of a conductor, and a printed circuit board (PCB) 17 on which circuit devices are mounted and a contact terminal is formed, and is manufactured by adhering a front end of the metal case 11 to the PCB 17. In this case, the metal case 11 and the PCB 17 are adhered to each other by using laser welding, electric welding, soldering, conductive adhesives, or the like.

### SUMMARY OF THE INVENTION

A conventional welding type condenser microphone has low adhesion between a case and a printed circuit board (PCB) due to low coupling properties between components, compared to a case when a curling method is used. That is, since portions that contact the PCB are not uniformly formed due to height tolerances generated during the manufacture of the components, planarization of a contact surface between the PCB and the case is not obtained, thereby reducing the adhesion between the case and the PCB.

Since the coupling properties between components are low compared to a case when a curling method is used, the quality of a welding type condenser microphone may easily deteriorate due to an external force. In particular, sensitivity is changed due to a change in a gap between a back plate and a diaphragm.

In addition, when an adhering method is used to adhere the PCB and the case to each other, components that are not secured may be easily separated from the case.

The present invention provides a welding type condenser microphone that is manufactured by using a curling method so as to reinforce the coupling properties between components, and a method of manufacturing the welding type condenser microphone.

The present invention also provides a welding type condenser microphone using curling and a method of manufacturing the same, which may increase the adhesion between the PCB and the case by closely supporting internal components by using a curling portion formed on the case and may reduce a change in sensitivity by preventing movement of the internal components due to an external force.

According to an aspect of the present invention, there is provided a welding type condenser microphone using curling, including a case sub assembly that is prevented from being moved by mounting a diaphragm, a spacer, a back plate, and a first base in a metal case having a hexahedral shape with an open side and then curling an end portion of the open side of the metal case; a printed circuit board (PCB) on which circuit devices and a second base are mounted; and an adhesion portion for adhering the case sub assembly and the PCB sub assembly to each other.

A curling portion may be formed on the end portion of the open side of the metal case and may be curled. Slits may be formed in opposite lower ends of the curling portion. In addition, two or more curling portions may be formed to face each other.

The metal case may have a hexahedral shape, and flange portions may be formed outwards on front ends of corners of the open side. A stumbling projection may be partially formed on the first base, grooves may be formed in the back plate to correspond to portions where the stumbling projection is not formed, and the first base and the back plate may be integrally combined with each other.

The second base may include a plate spring shape that is bent once, a U-shape plate spring having a wing, a circular coil spring, or a square coil spring.

According to another aspect of the present invention, there is provided a method of manufacturing a welding type condenser microphone using curling, the method including assembling a case sub assembly by stacking a diaphragm and a spacer in a metal case on which a curling portion is formed, putting a first base coupled to a back plate in the metal case, and then curling the curling portion of the metal case; assembling a PCB sub assembly by surface mounting technology (SMT)-mounting circuit devices and a second elastic base on a PCB substrate; and reversing the case sub assembly and adhering the case sub assembly to the PCB sub assembly.

The assembling of the case sub assembly may include stacking the diaphragm and the spacer in the metal case on which the curling portion is formed; coupling the first base on which a stumbling projection is partially formed and a back plate on which grooves are formed to each other so as to be integrally moved; installing the first based integrated with the back plate on the spacer included in the metal case; and curling the curling portion of the metal case.

A plurality of PCB sub assemblies may be arranged on a PCB raw board, and the case sub assembly and the PCB sub assembly may be adhered to each other and then may be separated from the PCB raw board by using a cutting process so as to be mass produced.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional welding type condenser microphone;

FIG. 2 is a flowchart of a method of manufacturing a welding type condenser microphone, according to an embodiment of the present invention;

FIG. 3 is a perspective view of a metal case of a welding type condenser microphone according to an embodiment of the present invention;

FIGS. 4A and 4B are perspective views of a first base and a back plate of a welding type condenser microphone according to an embodiment of the present invention;

FIG. 5 is a perspective view showing a case where internal components are inserted into a metal case of a welding type condenser microphone according to an embodiment of the present invention;

FIG. 6 is a perspective view of a case sub assembly that is complexly manufactured by curling a curling portion, according to an embodiment of the present invention;

FIG. 7 is an enlarged exploded perspective view of a case sub assembly of FIG. 6, according to an embodiment of the present invention;

FIG. 8 is an exploded perspective view of a welding type condenser microphone according to an embodiment of the present invention;

FIG. 9 shows a case where a plurality of individual PCB sub assemblies are arranged on a PCB raw board, according to an embodiment of the present invention;

FIG. 10 shows a case where a case sub assembly and a PCB assembly are coupled by using a laser and epoxy, according to an embodiment of the present invention;

FIG. 11 is a perspective view of a welding type condenser microphone according to an embodiment of the present invention; and

FIG. 12 is a cross-sectional view of a welding type condenser microphone according to an embodiment of the present invention.

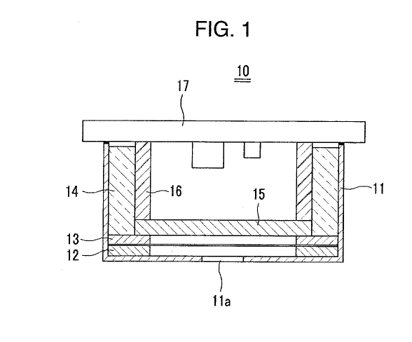

### DETAILED DESCRIPTION OF THE INVENTION

Hereinafter, one or more embodiments of the present invention will be described in detail with reference to the following examples. However, these examples are not intended to limit the purpose and scope of the one or more embodiments of the present invention.

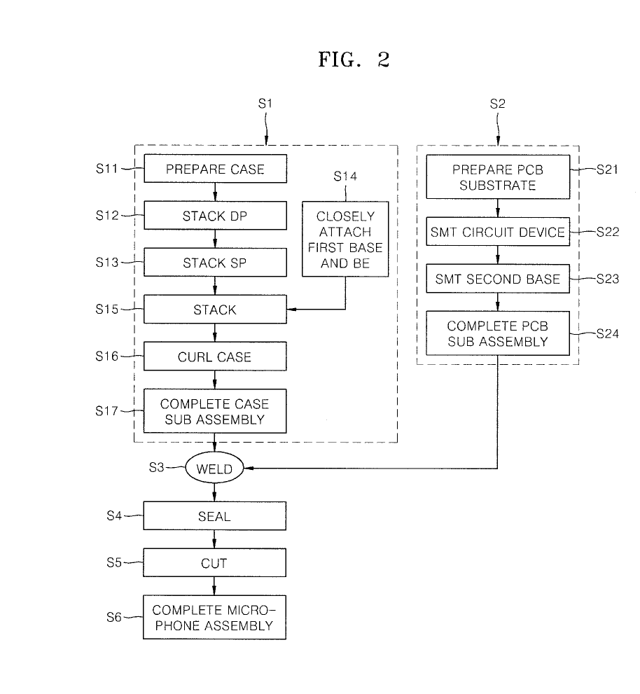

FIG. 2 is a flowchart of a method of manufacturing a welding type condenser microphone, according to an embodiment of the present invention.

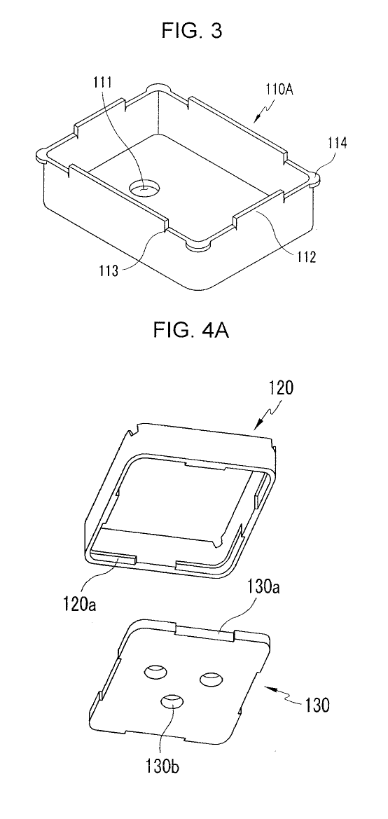

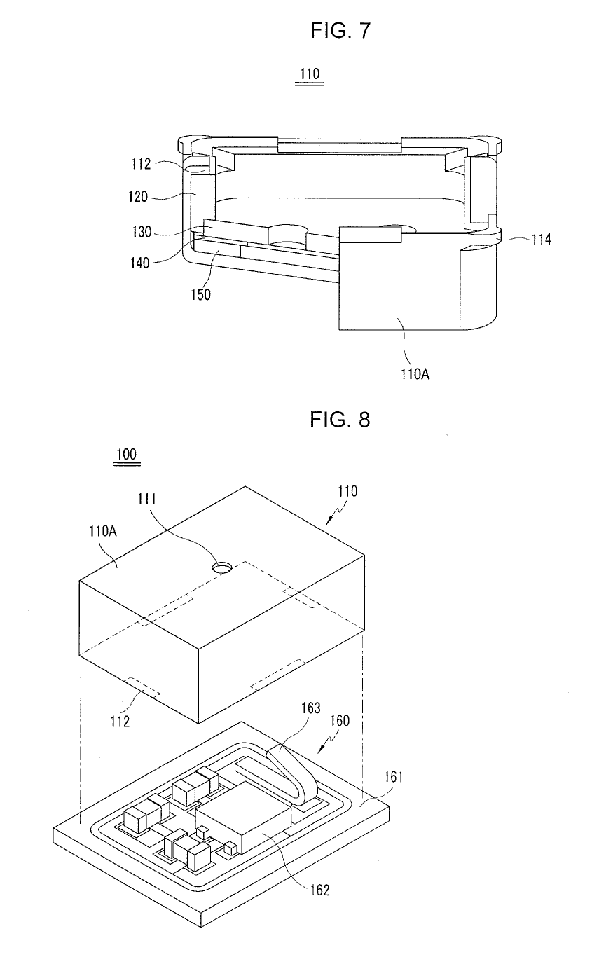

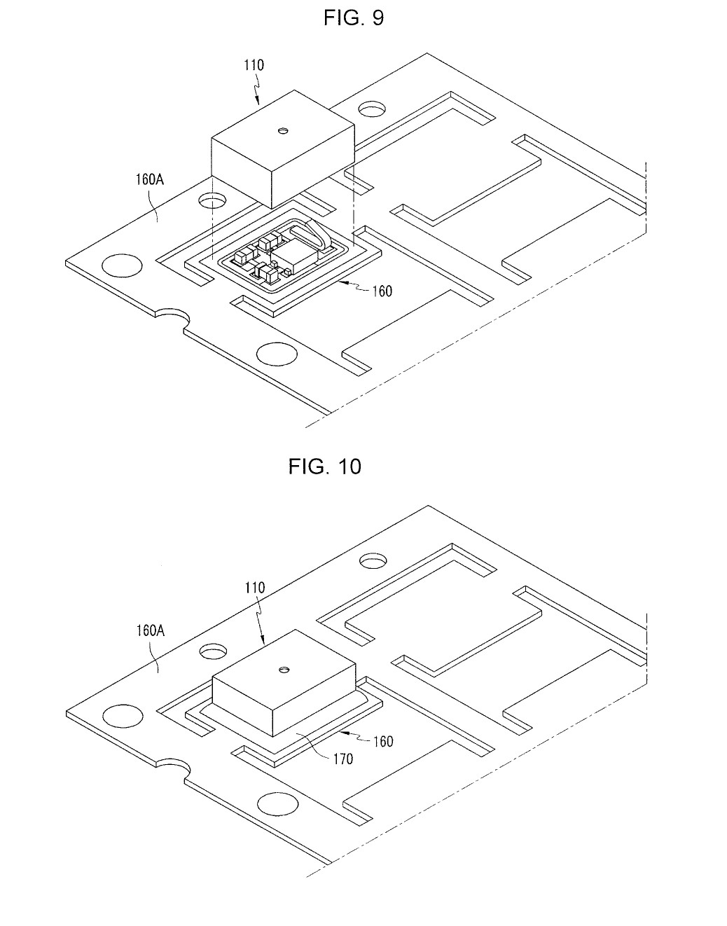

According to the present embodiment, the method of manufacturing the welding type condenser microphone includes operation S1 including stacking a diaphragm 150 (see FIG. 7) and a spacer 140 (see FIG. 7) in a metal case 110A including curling portions 112 (see FIG. 3) formed thereon, putting a first base 120 onto which a back plate 130 is pressed, and then curling the curling portions 112 of the metal case 110A to assemble a case sub assembly 110, operation S2 including surface mounting technology (SMT)-mounting circuit devices 162 and a second elastic base 163 on a printed circuit board (PCB) raw board 160A (see FIG. 9) to assemble a PCB sub assembly 160, and operations S3 to S6 including reversing the case sub assembly 110, accommodating the case sub assembly 110 on the PCB sub assembly 160 of the PCB raw board 160A, and adhering the case sub assembly 110 to the PCB sub assembly 160 and cutting a resulting structure to completely assemble an individual condenser microphone assembly, as shown in FIG. 2.

Referring to FIG. 2, in operation S1 of assembling the case sub assembly 110, the diaphragm (DP) 150 and the spacer SP 140 are sequentially stacked on a bottom surface of the metal case 110A that as a rectangular shape and includes the curling portions 112 formed thereon, as shown in FIG. 3 (S11, S12, and S13).

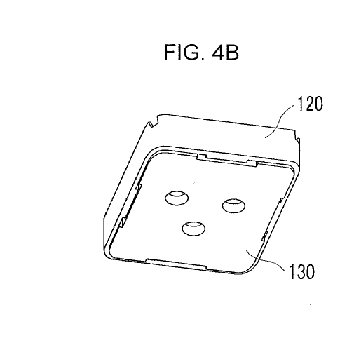

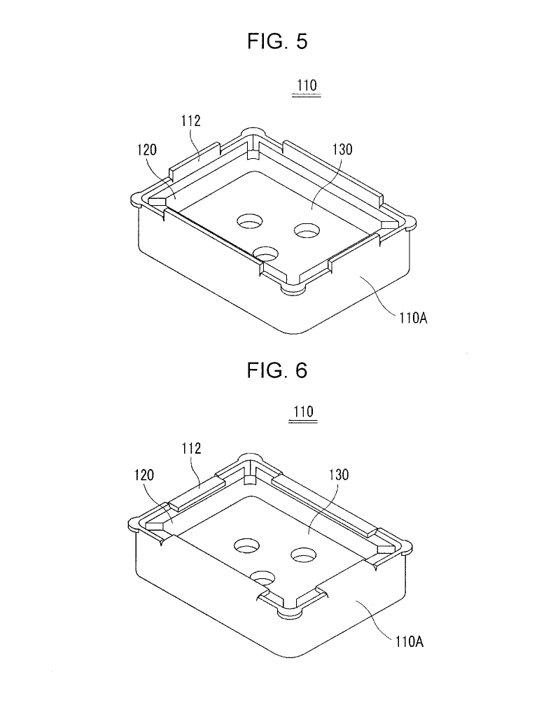

As shown in FIG. 4, the back plate 130 in which grooves 130a are formed is pressed onto the first base 120 on which a stumbling projection 120a is partially formed so as to be integrally moved. Then, as shown in FIG. 5, the first base 120 is stacked on a spacer 140 (see FIG. 7) mounted on the metal case 110A such that the back plate 130 may face the spacer 140 (S14 and S15).

Then, as shown in FIG. 6, the curling portions 112 of the metal case 110A are curled to completely assemble the case sub assembly 110 (S16 and S17).

In addition, in operation S2 of assembling the PCB sub assembly 160, the circuit devices 162 and the second elastic base 163 are SMT-mounted on a PCB substrate 161 and then a reflow process is performed to completely manufacture a plurality of individual PCB sub assemblies 160 on the PCB raw board 160A (S21 to S24), as shown in FIGS. 8 and 9. In this case, unnecessary portions of the PCB raw board 160A are perforated so as to easily cut the PCB raw board 160A into the individual PCB sub assemblies 160.

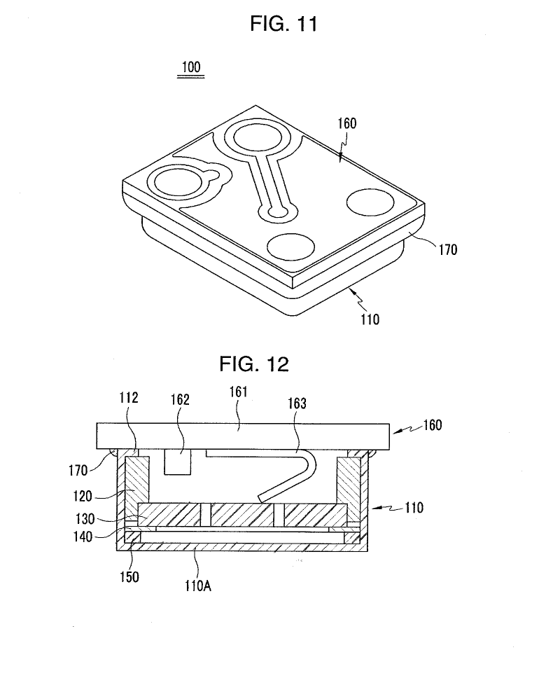

Then, as shown in FIG. 10, after the case sub assembly 110 that is completely assembled is reversed and is accommodated on the individual PCB sub assembly 160, the case sub assembly 110 and the PCB sub assembly 160 are welded by using a laser and sealed by using epoxy, and the case sub assembly 110 and the PCB sub assembly 160 are adhered to each other. Then, as shown in FIGS. 11 and 12, individual welding type condenser microphone assemblies are manufactured by cutting the case sub assembly 110 and the PCB sub assembly 160 into the individual components (S3 to S6). In this case, various methods such as laser welding, electric welding, soldering, or conductive adhesives may be used instead of the adhesion portion 170 for adhering the case sub assembly 110 and the PCB sub assembly 160 to each other.

Thus, according to the present embodiment, a curling method has advantages such as reinforcing the adhesion between components by curling the curling portions 112 of the metal case 110A to prevent movement of the components due to an external force when the diaphragm 150, the spacer 140, the back plate 130, and the first base 120 are mounted in the metal case 110A. That is, according to the present embodiment, the curling portions 112 exert a curling pressure onto the first base 120 so as to closely support internal components such as the back plate 130 and so on mounted on a lower portion of the first base 120, thereby preventing movement of the internal components.

In addition, since an elastic spring is used as the second elastic base 163, a contact failure that occurs due to height tolerances during the manufacture of components may be prevented. In addition, a contact surface between the PCB substrate 161 and the metal case 110A is uniformly obtained, thereby increasing the adhesion between the PCB substrate 161 and the metal case 110A.

Even if an external force is exerted on the metal case 110A, movement of the internal components, in particular, the back plate 130 and the diaphragm 150, is prevented. Thus, a change in a gap between the back plate 130 and the diaphragm 150 may be reduced to maintain sensitivity of the welding type condenser microphone. Te internal components in the case sub assembly 110, which are not secured when the case sub assembly 110 and the PCB sub assembly 160 are adhered to each other, may be prevented from being separated from each other.

FIG. 3 is a perspective view of a metal case 110A of a welding type condenser microphone according to an embodiment of the present invention.

Referring to FIG. 3, the metal case 110A has a hexahedral shape with an open side such that the diaphragm 150, the spacer 140, the back plate 130, and the first base 120 may be inserted into the metal case 110A. The curling portions 112 may be formed on a front end of the open side of the metal case 110A so as to closely support components inserted into the metal case 110A.

A sound hole 111 is formed in a bottom surface of the metal case 110A. The metal case 110A may have a hexahedral shape so as to easily manufacture and assemble the welding type condenser microphone and to increase the adhesion between the metal case 110A and the PCB sub assembly 160. In addition, corners of the metal case 110A may be rounded in order to increase the assembling properties of components and structural strength. Flange portions 114 may be formed outwards on front ends of the corners of the metal case 110A, respectively, and may increase a contact area with the PCB sub assembly 160, thereby increasing the adhesion between the metal case 110A and the PCB sub assembly 160.

Two or more curling portions 112 may be formed to face each other such that internal components inserted into the metal case 100A may be stably supported without being biased.

Slits 113 are formed in opposite lower ends of the curling portion 112 to a predetermined depth so as to facilitate curling and to prevent contact portions (portions except for the curling portions 112) of the metal case 110A from deforming during a curling process.

FIGS. 4A and 4B are perspective views of the first base 120 and the back plate 130 of a welding type condenser microphone according to an embodiment of the present invention. FIG. 4A shows a case where the first base 120 and the back plate 130 are not assembled. FIG. 4B shows a case where the first base 120 and the back plate 130 are assembled. In a conventional curling type condenser microphone, since a PCB substrate is put in a case and then curling is performed, components are not likely to be separated from the case. However, in the welding type condenser microphone according to the present embodiment, since the case sub assembly 110 is reversed for connection with the PCB sub assembly 160, there is a need to prevent the back plate 130 from being separated from the first base 120. To this end, according to the present embodiment, as shown in FIG. 4, the stumbling projection 120a is formed on the first base 120 so as to support the back plate 130 but still maintain insulation with the metal case 110A, and thus, even if the metal case 110A is reversed, the back plate 130 may not be separated from the first base 120.

Referring to FIG. 4A, the stumbling projection 120a is partially formed on the first base 120 of the welding type condenser microphone according to the present embodiment. The grooves 130a are formed on the back plate 130 to correspond to portions where the stumbling projection 120a is not formed. Thus, when the first base 120 and the back plate 130 are combined with each other, the first base 120 and the back plate 130 are pressed on each other so as to be integrally moved, as shown in FIG. 4B. Thus, the first base 120 and the back plate 130 may be easily mounted in a case. In addition, when the case is dropped, the back plate 130 may not be separated from the first base 120.

FIG. 5 is a perspective view showing a case where internal components are inserted into the metal case 110A of a welding type condenser microphone according to an embodiment of the present invention. FIG. 6 is a perspective view of the case sub assembly 110 that is complexly manufactured by curling the curling portion 112, according to an embodiment of the present invention. FIG. 7 is an enlarged exploded perspective view of the case sub assembly 110 of FIG. 6, according to an embodiment of the present invention.

Referring to FIGS. 5 through 7, the case sub assembly 110 is configured such that the diaphragm 150 and the spacer 140 are stacked on a bottom surface of the metal case 110A, and the back plate 130 is closely supported by the stumbling projection 120a of the first base 120 and also maintains insulation with the metal case 110A due to the first base 120. In addition, the first base 120 is supported by four sides of the curling portion 112 of a case, and thus, the first base 120 is strongly coupled to the internal components, thereby maintaining a stable state.

FIG. 8 is an exploded perspective view of a welding type condenser microphone according to an embodiment of the present invention. FIG. 9 shows a case where a plurality of individual PCB sub assemblies 160 are arranged on the PCB raw board 160A, according to an embodiment of the present invention. FIG. 10 shows a case where the case sub assembly 110 and the PCB sub assembly 160 are coupled by using a laser and epoxy, according to an embodiment of the present invention.

Referring to FIG. 8, the welding type condenser microphone 100 according to the present embodiment is completed by mounting the diaphragm 150, the spacer 140, the back plate 130, and the first base 120 in the metal case 110A that includes the sound hole 111 formed in a bottom surface thereof and having a hexahedral shape with an open side, and then adhering the case sub assembly 110, in which the curling portion 112 of the open side of the metal case 110A is curled, to the PCB sub assembly 160, in which the circuit devices 162 and the second elastic base 163 are mounted on the PCB substrate 161 by using an SMT method, by using the adhesion portion 170.

To this end, as shown in FIGS. 9 and 10, a plurality of PCB sub assemblies 160 of the welding type condenser microphone according to the present embodiment are arranged on the PCB raw board 160A so as to achieve easy mass production. In addition, the circuit devices 162 and the second elastic base 163 are mounted on the PCB sub assembly 160 by using an SMT method. According to the present embodiment, the second elastic base 163 has a plate spring shape that is bent once. Alternatively, various elastic springs such as a U-shape plate spring having a wing, a circular coil spring, a square coil spring, or the like may be used as the second elastic base 163. In addition, as shown in FIG. 10, when coupling is completely performed, individual microphones are separated from the PCB raw board 160A by using a cutting process.

The second elastic base 163 for electrically connecting the back plate 130 to the PCB substrate 161 may be embodied as a square coil spring that is pressed to the case sub assembly 110 without being mounted on the PCB substrate 161.

FIG. 11 is a perspective view of a welding type condenser microphone 100 according to an embodiment of the present invention. FIG. 12 is a cross-sectional view of the welding type condenser microphone 100 according to an embodiment of the present invention.

Referring to FIGS. 11 and 12, the welding type condenser microphone 100 is formed by adhering the case sub assembly 110 and the PCB sub assembly 160 to each other by using the adhesion portion 170, wherein the case sub assembly 110 is formed by curling the diaphragm 150, the spacer 140, the back plate 130, and the first base 120 to the metal case 110A, and the PCB sub assembly 160 is formed by mounting the circuit devices 162 and the second elastic base 163 on the PCB substrate 161 by using an SMT method. Various methods such as laser welding, electric welding, soldering, or conductive adhesives may be used instead of the adhesion portion 170.

The sound hole 111 is formed in the metal case 110A. The diaphragm 150 is connected to the metal case 110A through an electrode ring. The first base 120 is stacked together with the back plate 130 and exerts a force in a downward direction onto the back plate 130 and the spacer 140 and the diaphragm 150, which are disposed below the back plate 130, so as to prevent movement. The back plate 130 has a through hole formed therein and is a back electret plate formed of an electret.

Examples of the circuit devices 162 mounted on the PCB substrate 161 include a field effect transistor (FET), a capacitor, a resistor, or the like. The circuit devices 162 may apply voltages to the diaphragm 150 and the back plate 130 and may amplify a change in electrostatic capacity due to a sound pressure applied from an external source to output the change to an external circuit through a contact terminal.

In the welding type condenser microphone 100 according to the present embodiment, the spacer 140 is disposed between the diaphragm 150 and the back plate 130 that face each other, the diaphragm 150 is electrically connected to the PCB substrate 161 through the metal case 110A and the curling portion 112 of the metal case 110A, and the back plate 130 is electrically connected to the PCB substrate 161 through the second elastic base 163 formed of an elastic material to form an electrostatic capacity between the back plate 130 and the diaphragm 150.

In this case, when a sound pressure is applied from an external source through the sound hole 111, the diaphragm 150 vibrates and the electrostatic capacity changes. Thus, the sound pressure is converted into an electrical signal.

According to one or more embodiments of the present invention, a welding type condenser microphone is manufactured by closely supporting internal components by using a curling portion formed on a metal case such that a thickness difference between the internal components is reduced to increase the adhesion between a PCB sub assembly and a case sub assembly and movement of the components in the metal case due to an external force applied thereto is minimized so as to reduce a change in sensitivity, and a method of manufacturing the welding type condenser microphone is provided.

In addition, according to one or more embodiments of the present invention, an interference problem due to a thickness difference between the internal components may be overcome by using an electric spring structure as a second base. Assembling processes of a microphone may be simplified and a structure of the microphone may be stabilized by mounting the second base together with other components on a PCB substrate by using an SMT method.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A welding type condenser microphone using curling, comprising:
a case sub assembly that is prevented from moving by mounting a diaphragm, a spacer, a back plate, and a first base in a metal case having a hexahedral shape with an open side and then curling an end portion of the open side of the metal case;
a printed circuit board (PCB) on which circuit devices and a second base are mounted; and
an adhesion portion for adhering the case sub assembly and the PCB sub assembly to each other.

2. The welding type condenser microphone using curling of claim 1, wherein a curling portion is formed on the end portion of the open side of the metal case and is curled.

3. The welding type condenser microphone using curling of claim 2, wherein slits are formed in opposite lower ends of the curling portion.

4. The welding type condenser microphone using curling of claim 2, wherein two or more curling portions are formed to face each other.

5. The welding type condenser microphone using curling of claim 1, wherein the metal case has a hexahedral shape, and
wherein flange portions are formed outwards on front ends of corners of the open side.

6. The welding type condenser microphone using curling of claim 1, wherein a stumbling projection is partially formed on the first base,
wherein grooves are formed in the back plate to correspond to portions where the stumbling projection is not formed, and
wherein the first base and the back plate are integrally combined with each other.

7. The welding type condenser microphone using curling of claim 1, wherein the second base comprises a plate spring shape that is bent once, a U-shape plate spring having a wing, a circular coil spring, or a square coil spring.

8. The welding type condenser microphone using curling of claim 1, wherein the second base is a square coil spring that is pressed to the case sub assembly without being mounted on the PCB substrate.

9. A method of manufacturing a welding type condenser microphone using curling, the method comprising:
assembling a case sub assembly by stacking a diaphragm and a spacer in a metal case on which a curling portion is formed, putting a first base coupled to a back plate in the metal case, and curling the curling portion of the metal case;
assembling a PCB sub assembly by surface mounting technology (SMT)-mounting circuit devices and a second elastic base on a PCB substrate; and
reversing the case sub assembly and adhering the case sub assembly to the PCB sub assembly.

10. The method of claim 9, wherein the assembling of the case sub assembly comprises:
stacking the diaphragm and the spacer in the metal case on which the curling portion is formed;
coupling the first base on which a stumbling projection is partially formed and a back plate on which grooves are formed to each other so as to be integrally moved;
installing the first based integrated with the back plate on the spacer included in the metal case; and
curling the curling portion of the metal case.

11. The method of claim 9, wherein a plurality of PCB sub assemblies are arranged on a PCB raw board, and
wherein the case sub assembly and the PCB sub assembly are adhered to each other and then are separated from the PCB raw board by using a cutting process so as to be mass produced.
